(19) United States
(12) Patent Application Publication
(10) Pub. No.: US 2016/0146878 A1
(43) Pub. Date: May 26, 2016

(54) Electronic Assembly for Prognostics of Solder Joint

(71) Applicant: HITACHI, LTD., Chiyoda-ku, Tokyo (JP)

(72) Inventors: Lina Jaya DIGUNA, Tokyo (JP); Masahide OKAMOTO, Tokyo (JP); Kenji TAMAKI, Tokyo (JP)

(73) Assignee: Hitachi, Ltd., Chiyoda-ku, Tokyo (JP)

(21) Appl. No.: 14/899,909

(22) PCT Filed: Jul. 1, 2013
(86) PCT No.: PCT/JP2013/004081

§ 371 Date: Dec. 18, 2015

(51) Int. Cl. G01R 31/04; H01L 23/00; G01R 31/00

(52) U.S. Cl. CPC G01R 31/048; G01R 31/003; H01L 24/27; H01L 24/29; H01L 2224/27849; H01L 2224/32225; H01L 2224/29082; H01L 2924/20105; H01L 2224/29155; H01L 2224/29655; H01L 2224/27464; H01L 2224/27462; H01L 2924/01079

(57) ABSTRACT

The problem to be solved by the present invention is to provide a substrate for providing early warning of degradation in a semiconductor device.

The problem is solved by providing a substrate comprising an actual device comprising a semiconductor component and a solder joint, and a dummy device closely placed to the actual device on the substrate and connected electrically in parallel circuit to the actual device, comprising a dummy semiconductor component and a solder joint comprising an outer solder joint part and an inner solder joint part, wherein the outer solder joint part has same characteristic to the solder joint of the actual device and the inner solder joint part accelerates the crack growth faster than the outer solder joint, and percentage area of outer solder joint part is smaller than the predetermined failure criterion of delamination percentage in actual device corresponding to the threshold value of electrical change.

### TECHNICAL FIELD

The present invention relates to a substrate for providing early warning of degradation in a semiconductor device comprising an actual device and a solder joint and a dummy device closely placed to the actual device on the substrate; a dummy device thereof, method for manufacturing the dummy device; an inner solder joint part.

### BACKGROUND OF INVENTION

In electronic products including semiconductor devices, reliability and availability of the electronic products have been key issues because unexpected failure in actual use application can create huge financial cost and life-threatening consequence to end-users. If the sign of the occurrence of a failure can be detected before the failure occurs, it is possible to take measures such as perform maintenance in advance. For the dominant failure, this method also makes the product recovery easier and faster due to the known root cause of failure and increases the availability as consequence. Therefore, it has been desired an early warning and accurate prediction system of joint failure which can makes the possibility to take measure and perform maintenance in advance and a dummy device detecting the sign of the occurrence of a failure before the damage breaks out to cause the failure can be an effective failure prediction method.

In electronic products such as power device, the joint portions between semiconductor chip and substrate are damaged gradually by the application of external loads such as vibration and pressure. It has been a problem that loads resulting from heat generation and temperature fluctuations damage the joint because when temperature fluctuates, the difference between the thermal expansion coefficients of semiconductor chip and substrate makes the joint absorbs this difference of deformation amounts.

In semiconductor device, the degree of the solder joint damage of electronic device due to temperature fluctuation could be monitored by an adhered aluminum film on the corresponding substrate since there is correlation between the damage of solder joint and the delamination of adhered aluminum film measured with the change of resistance (Japanese Patent Publication 2010-62190).

The joint damage in ball grid array (BGA) could be predicted by the change in electrical resistance value due to the disconnection of the wire connected to the corner electrode pad in which the break strength the wire is lower than break strength of the bump join (Japanese Patent Application 2011-532853).

The joint damage caused by Kirkendall void and electromigration could be predicted by a structure comprising a conductor sandwiched with other conductor in which flowing current across the sandwich structure makes electrical failure (Japanese Patent Publication 2010-209199).

Lifetime of electronic component mounted on a circuit board could be predicted on the basis of the generated failure in the residual diagnosing device that has solder joint with the smaller heat conductivity than that of the actual component (Japanese Patent Publication 2011-252842).

### CITATION LIST

### Patent Literature

### [PTL 1]

### Japanese Patent Publication 2010-62190

### [PTL 2]

### Japanese Patent Application 2011-532853

### [PTL 3]

### Japanese Patent Publication 2010-209199

### [PTL 4]

### Japanese Patent Publication 2011-252842

### SUMMARY OF INVENTION

### Technical Problem

These different types of lifetime prediction, however, have the method in which the relation of the actual device and a device for detecting the sign of the occurrence of a failure should be firstly determined. Furthermore, these different methods were only applicable under a certain limited condition, so the lifetime prediction becomes less accurate under various application conditions because of its large variation. Therefore, it has been desired an adaptive dummy device which is applicable to various application conditions to detect the sign of the occurrence of a failure before the damage breaks out to cause the failure.

### Solution to Problem

The object of the present invention is solved by the following means.

(1) A substrate for providing early warning of degradation in a semiconductor device comprising: an actual device comprising a semiconductor component and a solder joint; and a dummy device closely placed to the actual device on the substrate and connected electrically in parallel circuit to the actual device, comprising a dummy semiconductor component and a solder joint comprising an outer solder joint part and an inner solder joint part, wherein the outer solder joint part has same characteristic to the solder joint of the actual device and the inner solder joint part accelerates the crack growth faster than the outer solder joint, and percentage area of outer solder joint part is smaller than the predetermined failure criterion of delamination percentage in actual device corresponding to the threshold value of electrical change.

(2) The substrate according to (1), further comprising one or more dummy device(s) closely placed to around of the actual device, connected electrically in parallel circuit to the other dummy device(s) and the actual device.

(3) A dummy device according to (1), wherein the inner solder joint part comprises the formation selected from a group consisting of brittle precipitation, brittle intermetallic compound and the formation of voids and weak strength solder joint at the interface.

(4) The dummy device according to (3), wherein the brittle precipitation and/or brittle intermetallic compound in the inner solder joint part is formed by using a barrier layer on the substrate, wherein the barrier layer for inner solder joint part is made of an electroless Ni (or Ni with high impurity content such as NiP) and the barrier layer for outer solder joint part is made of an electrolytic Ni.

(5) The dummy device according to (3), wherein the formation of voids is the extensive formation of Kirkendall voids.

(6) Method for manufacturing the dummy device according to (5),
providing the extensive formation of Kirkendall voids into the inner solder joint part by using a substrate surface of which the thickness of the barrier layer for the inner solder joint part of the substrate surface is thinner than the thickness of the barrier layer for the outer solder joint part;
obtaining the thickness of the barrier layer for the inner solder joint part which is equal to or less than 80% of the thickness of the barrier layer for the outer solder joint part; and,
exposing the inner solder joint part to the temperature above 150° C. after reflow soldering process and/or during the actual application environment above 150° C., wherein this method is applicable to high temperature condition (above 150° C.).

(7) Method for manufacturing the dummy device according to (6), wherein the substrate surface is a dummy semiconductor chip surface.

(8) Method for manufacturing the dummy device according to (3), wherein the formation of voids and or weak strength solder joint at the interface is performed by the poor solder wettability on the substrate surface or dummy semiconductor chip surface for the inner solder joint part during the reflow process.

(9) Method for manufacturing the dummy device according to (8), wherein the gold coating thickness of substrate surface for the inner solder joint part is equal to or less than 30% of thickness of the substrate surface for the outer solder joint part.

(10) Method for manufacturing the dummy device according to (8), wherein the gold coating thickness of a semiconductor chip surface for the inner solder joint part is equal to or less than 30% of the gold coating thickness of semiconductor chip surface for the outer solder joint part.

(11) Method for manufacturing the dummy device according to (8), wherein an oxide layer with the thickness equal to or more than 1 nm is formed on the one side and/or both sides of the solder film surface corresponding to the inner solder joint part by O₂ plasma, and wherein the solder film surface corresponding to the outer solder joint part is covered with a mask to prevent the oxide layer from being formed on the outer solder joint part of solder film.

(12) Method for manufacturing the dummy device according to (3), wherein the voids in the inner solder joint part are formed as trapped air during the reflow soldering process by using the discontinuous structure in the middle part of the solder film.

(13) Method for manufacturing the dummy device according to (12), wherein solder film is patterned with some holes in the middle part or solder film.

(14) Method for manufacturing the dummy device according to (12), wherein solder film is patterned with an open area or a big hole filled with some solder balls in the middle part of solder film.

(15) An inner solder joint part according to (1) comprising the formation selected from a group consisting of brittle precipitation, brittle intermetallic compound and the formation of voids.

(16) The inner solder joint part according to (15), wherein the brittle precipitation and/or brittle intermetallic compound is formed by a barrier layer on the substrate, wherein the barrier layer for inner solder joint part is made of an electroless Ni and the barrier layer for outer solder joint part is made of an electrolytic Ni.

(17) The inner solder joint part according to (15), wherein the formation of voids is the extensive formation of Kirkendall voids.

(18) The inner solder joint part according to (17), wherein the extensive formation of Kirkendall voids is provided by using the substrate surface and/or the semiconductor chip surface comprising the thickness of the barrier layer for the inner solder joint part is equal to or less than 80% the thickness of the barrier layer for the outer solder joint part.

(19) The inner solder joint part according to (15), wherein the formation of voids and/or weak strength solder joint at the interface are formed by the poor solder wettability on the substrate surface and/or the semiconductor chip surface for the inner solder joint part during the reflow process.

(20) The inner solder joint part according to (19), wherein the gold coating thickness of surface for the inner solder joint part is equal to or less than 30% of the gold coating thickness of the surface for the outer solder joint part.

(21) The inner solder joint part according to (19), wherein the solder film with an oxide layer with the thickness equal to or more than 1 nm is formed on the one side and/or both sides of the solder film surface corresponding to the inner solder joint part by O₂ plasma, wherein the solder film surface corresponding to the outer solder joint part is covered with a mask to prevent the oxide layer from being formed on the solder film surface corresponding to the outer solder joint part.

(22) The inner solder joint part according to (15) comprising voids, wherein the voids are formed as trapped air during the reflow process by using the solder film with the discontinuous structure in the middle part of solder film.

(23) The inner solder joint part according to (22), wherein the discontinuous structured solder film is patterned with some holes in the middle part or solder film.

(24) The inner solder joint part according to (22), wherein the discontinuous structured solder film is patterned with an open area or a big hole filled with some solder balls in the middle part of solder film.

### Advantageous Effects of Invention

The present invention can accurately and early predict lifetime and warn degradation in a semiconductor device. The present invention also can warn and predict early warning of solder joint failure in actual use application including unpredicted and unanticipated failure which occurs due to different usage environments. The present invention also can predict more accurate the joint failure with adjustable predicting time. Adjacent actual and dummy device(s) of the present invention can reduce effect of variation and makes high precision of prognostics. By changing an area ratio of an outer solder joint part/an inner solder joint part in dummy device, the lifetime prediction in the present invention can be adjustable to any predetermined lifetime criteria. The early warning of a dummy device can eliminates the unpredicted failure of an actual device in actual use application.

### BRIEF DESCRIPTION OF DRAWINGS

FIG. 1 shows a cross-section of a substrate comprising adjacent devices with different characteristic of a solder joint.

FIG. 2 is a graph showing the percentage change of a damaged solder joint area and the number of temperature cycles in temperature cycling test for devices with normal and fragile solder joints.

FIG. 3 shows the cross section of the substrate of the present invention comprising an adjacent actual device and a dummy device.

FIG. 4 shows the sectional view of a solder joint layer of a dummy device.

FIG. 5 is a graph showing the percentage change of a solder joint area and the number of cycles for an actual device and a dummy device.

FIG. 6 is a graph showing the percentage change of a solder joint area and the number cycles for an actual device and dummy devices with the increasing smaller percentage area of outer solder joint part.

FIG. 7 shows the sectional view of the substrate comprising an adjacent actual device and some dummy devices.

FIG. 8 is a block diagram illustrating an exemplary electrical circuit of the first embodiment.

FIG. 9 is graph showing the voltage change and the number of cycles for an actual device and dummy devices with the increasing smaller percentage area of an outer solder joint part.

FIG. 10 is a graph showing the lifetime prediction of an actual device according to the lifetimes of dummy devices.

FIG. 11 is a block diagram illustrating an exemplary system for providing early warning of actual device failure.

FIG. 12 shows the first example of the dummy device and the manufacturing method.

FIG. 13 shows the second example of the dummy device.

FIG. 14 shows the second example of the manufacturing method of the dummy device.

FIG. 15 shows the third example of the manufacturing method of the dummy device.

FIG. 16 shows the fourth example of the manufacturing method of the dummy device.

FIG. 17 shows the fifth example of the manufacturing method of the dummy device.

FIG. 18 shows the sixth example of the manufacturing method of the dummy device.

FIG. 19 shows the seventh example of the manufacturing method of the dummy device.

FIG. 20 shows the eight example of the manufacturing method of the dummy device.

### DESCRIPTION OF EMBODIMENTS

### 1. Present Invention

The present invention relates to a substrate for providing early warning of degradation in a semiconductor device and manufacturing methods thereof; a dummy device and manufacturing methods thereof, an inner solder joint part of the solder joint of the dummy device and manufacturing methods thereof. One object of the present invention is to provide method and a dummy device to determine early warning of solder joint failure in actual use application including unpredicted and unanticipated failure which occurs due to different usage environments. Another object of the present invention is to provide methods and dummy devices to predict more accurate joint failure with adjustable predicting time. Each of the present inventions is described in detail as below.

### 2. Substrate of the Present Invention

The present invention relates to a substrate for providing early warning of degradation in a semiconductor device comprising: an actual device comprising a semiconductor component and a solder joint; and a dummy device closely placed to the actual device on the substrate comprising a dummy semiconductor component and a solder joint comprising an outer solder joint part and an inner solder joint part, wherein the outer solder joint part has same characteristic to the solder joint of the actual device and the inner solder joint part accelerates the crack growth faster than the outer solder joint, and percentage area of the damaged outer solder joint part is smaller than the predetermined failure criterion of delamination percentage in the actual device.

One object of the substrate of the present invention is to determine early warning of solder joint failure in actual use application including unpredicted and unanticipated failure which occurs due to different usage environments. Another object of the present invention is to provide methods and dummy devices to predict more accurate the joint failure with adjustable predicting time.

An actual device used as a functional device contributing to the system performance comprises a semiconductor component and a solder joint, for example, electronic device, preferably, a semiconductor device. A dummy device used as a nonfunctional device without contribution to the system performance is described in detail below.

The detection of the joint failure is performed by the temperature cycling test and the percentage of the damaged joint area is measured. The damage means crack or crack growth. The temperature cycling test is an accelerated test consisting of repeated alternate exposures to high and low temperature extremes at relatively high rates of temperature change. At first, the crack growth in the joint layer of the dummy device and the actual device undergoes the same way because the characteristic of the outer solder joint part of the dummy device is same as that of the solder joint layer of the actual device. When the cracks proceeds into the inner solder joint part of the dummy device, the crack growth is more accelerated than that in the actual device and the dummy device reaches the failure criterion before the actual device reaches the failure criterion. By the acceleration of crack growth in the dummy device, the dummy device reaches the failure criterion before the actual device reaches the failure criterion; whereby the accurate lifetime of the actual device is predicted.

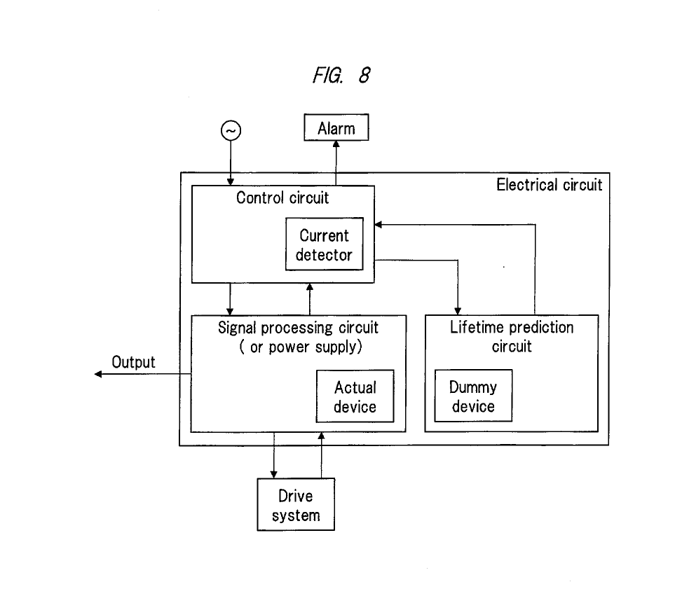

One embodiment on an electrical circuit of the substrate of the present invention is shown in FIG. 8. The actual device is contained in signal processing circuit and the dummy device is contained in the life time prediction circuit. The damage in the solder joint layer of both the actual device and the dummy device is electrically detected, respectively, and compared each other with a current detector in a control circuit. Once the dummy device reaches the failure criterion, an alarm is activated so that the imminent failure of the actual device is indicated.

### 3. Dummy Device of the Present Invention

The “dummy device” means a nonfunctional device for detecting the sign of the occurrence of a failure before the damage breaks out to cause the failure. The dummy device is closely placed to the actual device on the substrate and is connected electrically in parallel circuit with the actual device. The dummy device comprises a dummy semiconductor component and a solder joint comprising a joint layer consisting of an outer solder joint part and an inner solder joint part. The outer solder joint part has basically the same characteristic to the solder joint of the actual device and the inner solder joint part is more sensitive to the load than the outer solder joint part and accelerates the crack growth faster than the outer solder joint.

The dummy devices are configured to detect the imminent electrical failure of the actual device when the electrical change of dummy devices exceeds orderly a predetermined threshold value ahead of the actual device wherein the dummy devices have increasing fragility of the inner solder joint part and or increasing smaller percentage areas of the outer solder joint part.

In the initial lifecycle environment, the dummy device undergoes the same way as actual device in which crack initiates from the edges and grows across the joint until certain time before the predetermined failure criterion, growth of crack in the joint of the dummy device is accelerated when it enters the inner joint part and the dummy device fails earlier before the actual device and alarms the imminent failure of the actual device.

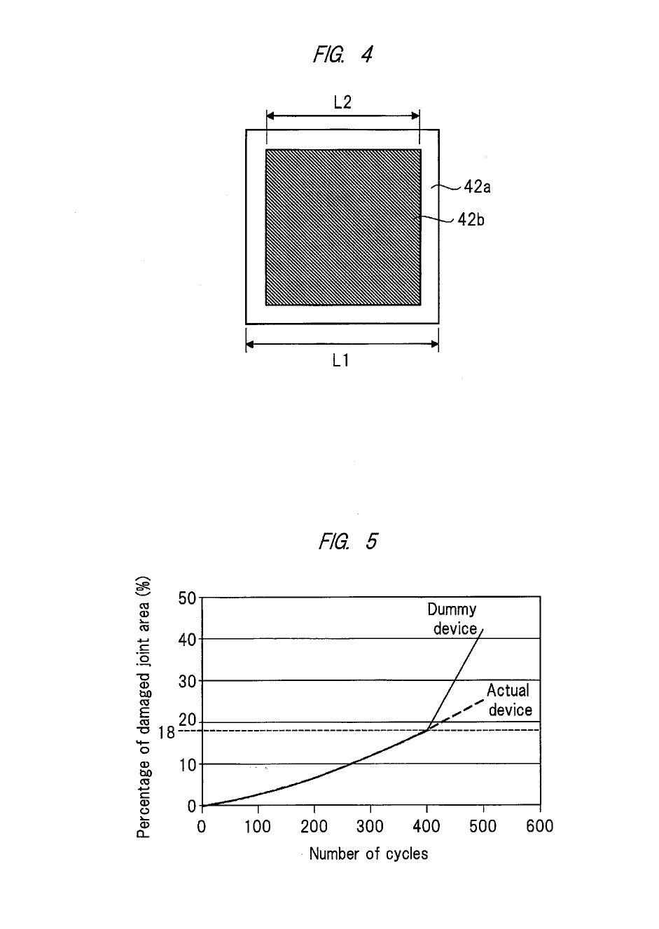

As shown in FIG. 4, the length of the solder joint side L1 can be different or same as the length of rectangular side thereof. The length of the inner solder joint side L2 can be different or same as the length of rectangular side thereof. Percentage area of the outer solder joint area is smaller than the predetermined failure criterion, e.g. certain delamination percentage of the solder joint. Said that L1 is same as the length of rectangular side thereof, so (L1²−L2²)/L1²×100%<delamination percentage predetermined as failure criterion.

The percentage area of the outer solder joint part is smaller than the predetermined failure criterion of delamination percentage in the actual device. As shown in FIG. 5, after the cracks proceed into the inner solder joint part of the dummy device, the crack growth is more accelerated than that of the actual device, wherein the percentage of the damaged joint area at the change place from the outer solder joint part to the inner solder join part is below than the certain delamination percentage of the solder joint predetermined as failure criterion. Changing from the outer solder joint part to the inner solder joint part, the percentage increase of the damaged joint area over the cycle or time is higher than that of the actual device and then the dummy device reaches the failure criterion earlier than the actual device. The description “failure criterion of delamination percentage” means the index indicating the lifetime of the actual device. As described above, the damage in the solder joint layer of both the actual device and the dummy device is electrically detected and once the dummy device reaches the failure criterion, an alarm is activated so that the imminent failure of the actual device indicates.

Delamination of the older joint in the device impairs heat transfer from the semiconductor chip to the substrate and consequently causes the increased thermal resistance, a measure of how fast heat can be dissipated from the semiconductor. Since the increased thermal resistance restricts performance of the device, it is commonly used to define the device lifetime. As thermal resistance increases, temperature of the device increases as consequence. Thus, the increase of thermal resistance due to the delamination of the solder joint can be detected electrically by the change of temperature-dependent device parameter such as the device voltage. At predetermined thermal resistance as criterion of device lifetime or index of thermal resistance, the corresponding delamination of the solder joint is defined to the threshold value of voltage change.

As shown in FIG. 9, it is understood the correlation among the Ratio of L2/L1 of dummy devices, the voltage measured by the current detector and the number of the cycles of the temperature cycling test on the actual device and dummy devices of the present invention. The smaller the Ratio of L2/L1 of dummy devices is, that is, the larger percentage area of the outer solder joint part is, the later the dummy device to the failure criterion reaches. Also, the lifetime or the time to failure of the dummy device becomes longer if the ratio of L2/L1 in the solder joint decreases.

In the present invention, warning of actual device failure may be performed by the following system. For example, when the electrical signal of the dummy device is monitored and compared with the failure criterion or index of thermal resistance, once the electrical signal of the dummy device reaches the threshold value of voltage change, such as “delta V_{DS}^{”} or the change of drain-to-source voltage in power MOSFET devices, an alarm is activated and informs the needs to perform maintenance action.

The dummy device is also called as a canary device which is a detector whose name is derived from a canary once used for detecting poison gas in coal mines. In the use of the canary device, a detecting device (canary device) is disposed at a point carrying a larger load than on a joint to be measured and then a failure is caused to occur earlier before the actual device and alarms the imminent failure of actual device. Thus, the imminent failure of the actual device can be predicted.

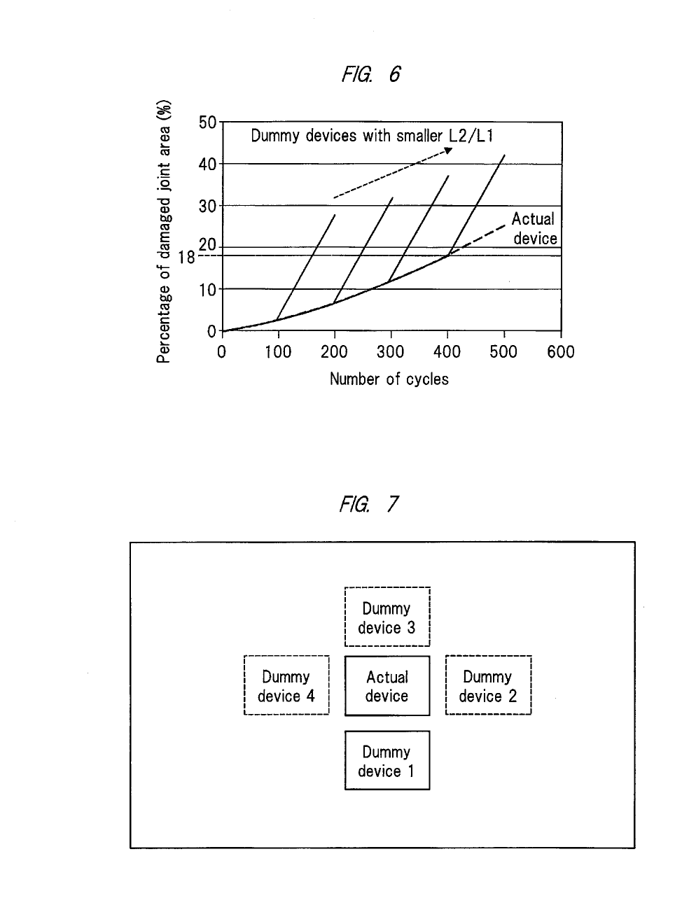

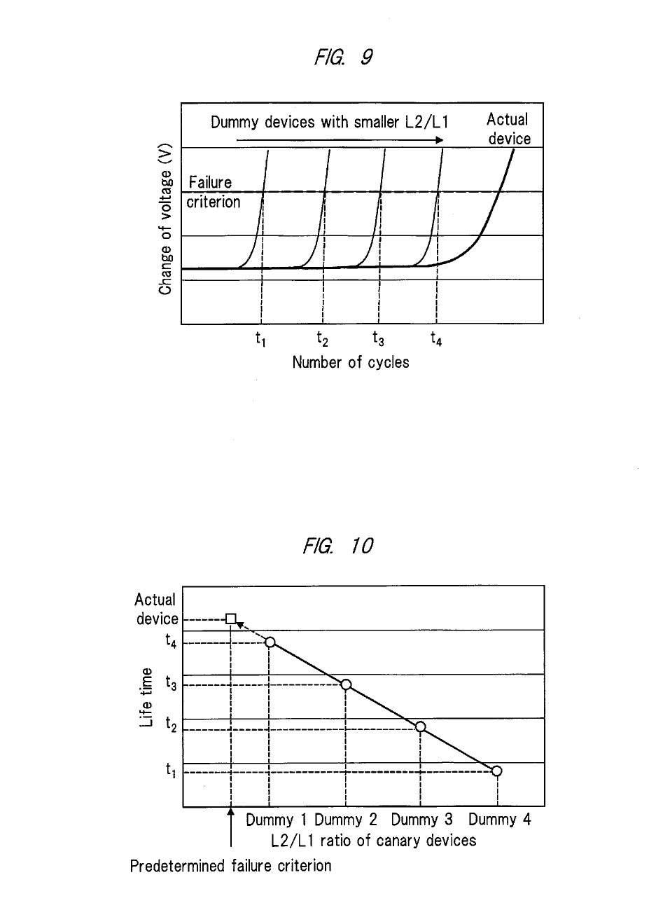

The substrate of the present invention may comprise two or more dummy devices as shown in FIG. 7. When the substrate has plural of dummy devices, those are connected electrically in a parallel circuit with to the other dummy device(s) each other and the actual device. Each of dummy devices of the present invention may have different ratio of L2/L1 in the solder joint layer and it makes different warning intensity of the actual device failure. As shown in FIGS. 6 and 9, the smaller ratio L2/L1 is, the later the crack growth starts to be accelerated and the later dummy device reaches failure criterion. This means, dummy devices with smaller ratio of L2/L1 in the solder joint layer will have higher warning intensity when the dummy device fails. According to the ratio of L2/L1, lifetime of the dummy device can be easily adjusted as needed for actual application, such as at the time before the periodic maintenance schedule and the following occurrence of the actual device failure, so that unnecessary maintenance action can be reduced and the maintenance cost as consequence. The dummy device with smaller percentage area of the outer solder joint part or with larger L2/L1 fails earlier than those with the larger percentage area or with smaller L2/L1. The failure trend of dummy devices determines accurately the occurrence of the actual device failure as shown in FIG. 10. Therefore, the substrate of the present invention with plural of dummy devices can obtain higher warning accuracy for the actual device failure because of combination of their different warning intensity and can warn about the lifetime of the actual device not just one time.

### 4. Inner Solder Joint Part of the Dummy Device of the Present Invention

The dummy device of the present invention comprises a dummy semiconductor component and a solder joint comprising an outer solder joint part and an inner solder joint part. The inner solder joint part is more fragile than the outer solder joint part, it means, the inner solder joint part accelerates the crack growth faster than the outer solder joint. The inner solder joint part is fragile due to the existence of at least one selected from the group consisting of brittle precipitation, brittle intermetallic compound, the formation of voids and weak strength solder joint at the interface.

Brittle precipitation and/or brittle intermetallic compound included in the inner solder joint part cause fragility and limit the mechanical strength of the inner solder joint part. The brittle precipitation and/or brittle intermetallic compound are originated by the impurity in the substrate coating such as in an electroless Ni barrier layer wherein it contains phosphorous (P) as impurity. This phosphorus impurity diffuses to the inner solder joint part and creates P-rich precipitation and/or P-rich intermetallic compound which are brittle. The outer solder joint part also has the barrier layer, but it is an electrolytic barrier layer, for example an electrolytic Ni.

The inner solder joint part may be fragile due to the formation of voids therein. Preferable formation of voids includes Kirkendall voids, but not limited to the above. Kirkendall voids means voids formed due to the imbalance in the diffusion rates of metal atoms across an interface of two dissimilar materials. A barrier layer is placed on a substrate surface to prevent the diffusion of solder component to the substrate. Thinner barrier layer, the extensive Kirkendall voids are formed at the interface. Extensive Kirkendall voids in the inner solder joint part relative to the outer solder joint part are formed when the thickness of a barrier layer for the inner solder joint part on the substrate surface is thinner than the thickness of a barrier layer for the outer solder joint part upon the exposure to the high temperature above 150° C. The substrate surface may be a semiconductor chip surface. In this case, the chip may also has the thinner barrier layer for the inner solder joint part on the chip surface relative to the barrier layer for the outer solder joint part on the chip substrate.

The voids in the inner solder joint part may be formed when solder wettability on the substrate surface or the semiconductor chip surface for the inner solder joint part is poor during reflow process, wherein a melted solder improperly wets the surface of a substrate and/or a chip. Poor solder wettability also create weak strength of the solder joint at the joint interface instead of voids. Formation of an oxide layer on the surface of the substrate and/or the chip inhibits the wetting of a melted solder. The use of gold coating on the surface of the substrate and/or the semiconductor surface prevents oxygen from the surface and protects it from oxidation. The poor solder wettability on the substrate surface for the inner solder joint part relative to the outer solder joint part may be obtained by using the gold coating on substrate surface having the thickness for the inner solder joint part equal to or less than 30% of thickness of the gold coating for the outer solder joint part.

The substrate surface may be a semiconductor chip surface, wherein the poor solder wettability on the chip surface for the inner solder joint part relative to the outer solder joint part may be obtained by using the gold coating on chip surface having the thickness for the inner solder joint part equal to or less than 30% of thickness of the gold coating for the outer solder joint part.

The poor solder wettability may be obtained by oxidizing the solder film surface for the inner solder joint part by O₂ plasma. The solder film refers to the initial solder material in the film form before the reflow process. Oxidation on the solder film for the inner solder joint part can be performed on one or both sides of the solder film. The resulted oxide layer may have the thickness equal to or more than 1 nm. Then, voids are occurred in the inner solder joint part due to the poor solder wettability. In this case, the solder film surface for the outer solder joint part is not oxidized. To prevent the oxide layer from being formed on the outer solder joint part of the solder film, the surface for the outer solder joint part is covered with a removable mask.

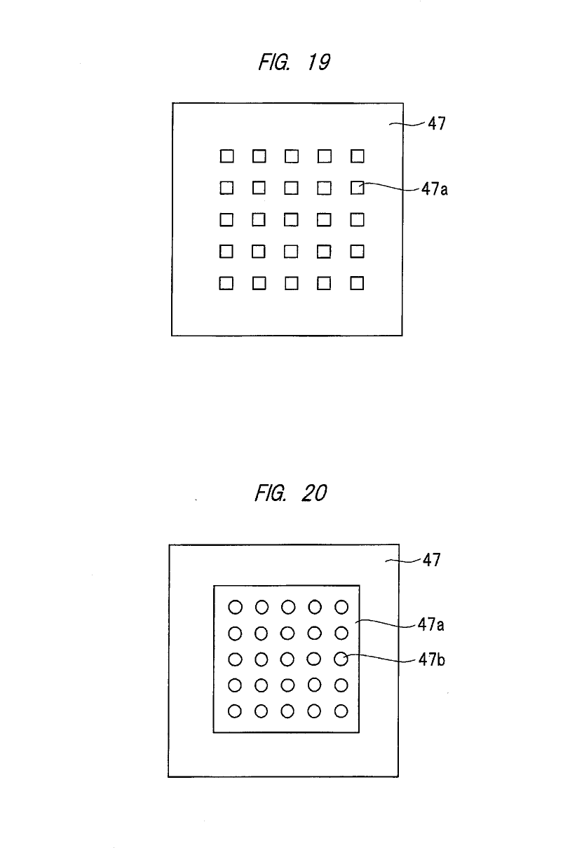

The voids in the inner solder joint part may be formed as trapped air by using the solder film with the discontinuous structure in the middle part. The discontinuous structure may be a solder film patterned with some holes in the middle part of the solder film (FIG. 19), or a solder film pattern with an open area or a big hole filled with some solder balls in the middle of the solder film (FIG. 20).

### 5. Method for Manufacturing Dummy Device

The dummy device comprising the formation of voids in inner solder joint part is manufactured by the following steps:
providing the extensive formation of Kirkendall voids into the inner solder joint part by using a substrate surface of which the thickness of the barrier layer for the inner solder joint part of the substrate surface is thinner than the thickness of the barrier layer for the outer solder joint part;
obtaining the thickness of the barrier layer for the inner solder joint part which is equal to or less than 80% of the thickness of the barrier layer for the outer solder joint part; and,
exposing the inner solder joint part to the temperature above 150° C. after reflow soldering process and/or during the actual application environment above 150° C., wherein this method is applicable to high temperature condition (above 150° C.).

In the above method, the substrate may be a metalized substrate. The substrate surface of which the thickness of the barrier layer for the inner solder joint part is thinner than the thickness of the barrier layer for the outer solder joint part, may be a semiconductor chip surface.

In the present invention, the voids in the inner solder joint part may be formed when the solder wettability on the substrate surface or the semiconductor chip surface for the inner solder joint part is poor during the reflow process. The poor solder wettability on the substrate surface for the inner solder joint part relative to the outer solder joint part is formed by using the gold coating on the substrate surface having the thickness for the inner solder joint part equal or less than 30% of thickness of gold coating on the substrate surface and the semiconductor chip surface for the outer solder joint part.

In the above method, the gold coating thickness of the semiconductor chip surface for the inner solder joint part may be equal to or less than 30% of the gold finish thickness of semiconductor chip surface for the barrier layer for the outer solder joint part.

The poor solder wettability may be obtained by oxidizing the surface for the inner solder joint part of a solder film by O₂ plasma. Oxidation on the solder film for the inner joint part can be performed on one or both sides of the solder film. The resulted oxide layer may have the thickness equal to or more than 1 nm. Then, voids are formed in the inner solder joint part due to poor solder wettability. In this case, the surface of the solder film for the outer solder joint part is not oxidized and during the oxidization, the surface for the outer solder joint part of the solder film is covered with a mask to prevent the oxide layer from being formed on the solder film for the outer solder joint part.

### 6. Hereinafter, Embodiments of the Present Invention are Described in Detail on the Basis of Drawings

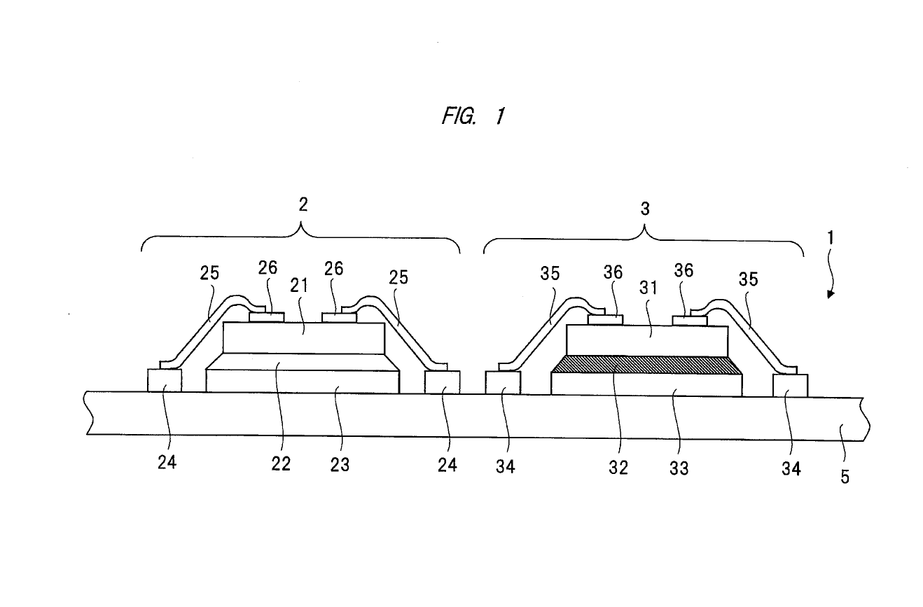

FIG. 1 is a cross-section of a substrate comprising adjacent devices with different characteristics of a solder joint. A substrate 5 is a substrate for mounting semiconductor chips 21 and 31 in which are joined on the surface of the substrate 5 via a normal solder joint 22 and a fragile solder joint 32, respectively. The device 3 is a same device as a device 2 other than having a fragile solder joint and it should be noted that the device 3 with a fragile joint 32 does not relate to the dummy device of the present invention.

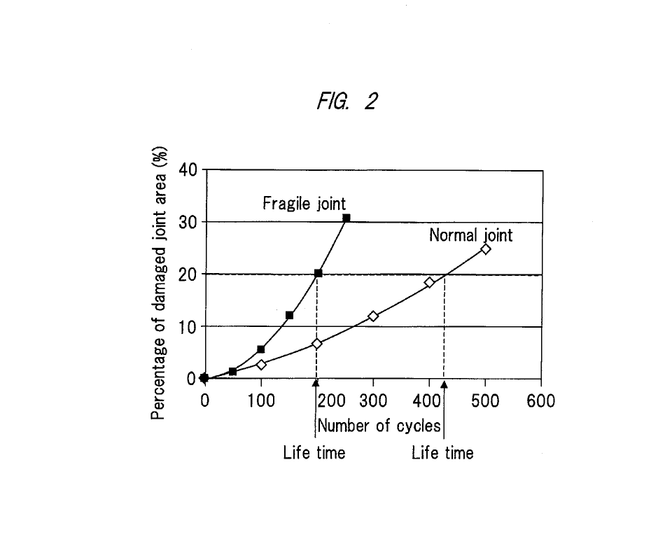

FIG. 2 shows the percentage change of a damaged solder joint area and the number of cycles under temperature cycling test for devices with a normal solder joint 22 and a fragile solder joint 32. As shown in FIG. 2, a device 3 with the fragile joint 32 shows faster increase in the percentage of damaged solder joint area than the device 2 with the normal joint 22, it means, the solder joint of the device 3 is damaged faster than the solder joint of the device 2.

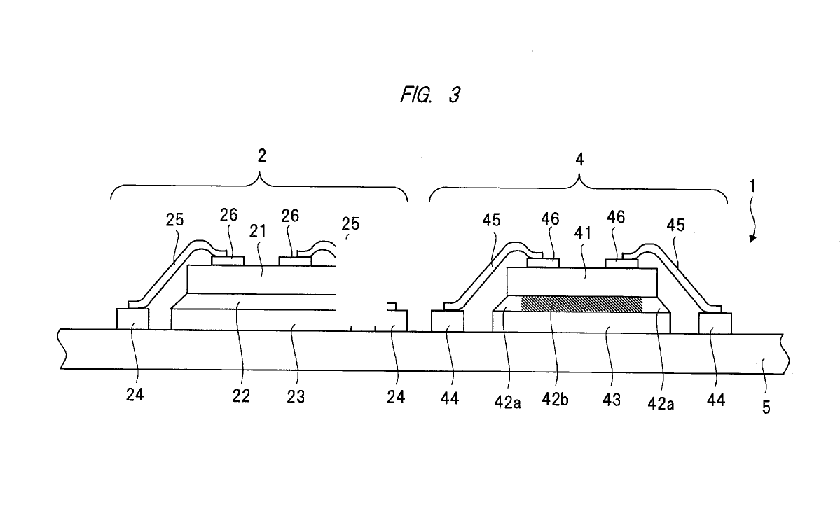

FIG. 3 is a cross-section of the substrate independently comprising adjacent an actual device 2 and a dummy device 4. A substrate 5 is a substrate for mounting a semiconductor chip 21 of the actual device 2 and a dummy semiconductor chip 41 of the dummy device 4. The semiconductor chip 21 is joined on the surface of the substrate 5 via a normal solder joint 22 and the dummy semiconductor chip 41 is joined on the surface of the substrate 5 via a solder joint of dummy device 42. The solder joint 42 has the outer solder joint part 42a and the inner solder joint part 42b. The inner solder joint part 42b is more fragile than the outer solder joint part 42a and the outer solder joint part 42a is same to the solder joint 22 of the actual device 2.

FIG. 4 shows the sectional view of the solder joint layer of dummy device. The solder joint layer has the outer solder joint part 42a and the inner solder joint part 42b. The length of the solder joint side L1 can be different or same as the length of rectangular side thereof. The length of the inner solder joint side L2 can be different or same as the length of rectangular side thereof. Percentage area of outer solder joint area is smaller than the predetermined failure criterion, e.g. certain delamination percentage of the solder joint. Said that the L1 is same as the length of rectangular side thereof, so (L1²−L2²)/L1²×100%<delamination percentage predetermined as failure criterion.

FIG. 5 shows the percentage of damaged joint area in the actual device 2 and the dummy device 4 under the temperature cycling test. The damage means crack or crack growth.

As shown in FIG. 5, the crack growth in the joint layer of the dummy device 4 and the actual device 2 undergoes the same way because the same characteristic of the outer solder joint part 42a of the dummy device 4 and the solder joint layer 22 of the actual device 2. When the cracks proceeds into the inner solder joint part 42b of the solder joint of the dummy device 4 at 18% damaged joint area in this graph, the crack growth is accelerated and the dummy device 4 reaches the failure criterion which is 20% of damaged joint area or more. Crack growth in the dummy device 4 is accelerated just before the actual device 2 reaches the failure criterion and this makes the accurate lifetime prediction of the actual device 2.

FIG. 6 shows the percentage change of a damaged solder joint area and the number of cycles for the actual device 2 and dummy devices 4 with the decreasing percentage area of inner solder joint part 42b, L2/L1. As shown in FIG. 6, time for the dummy device 4 reaching failure criterion or lifetime becomes longer as decreasing the percentage area of the inner solder joint part 42b, L2/L1. According to the ratio of L2/L1, lifetime of the dummy device 4 can be easily adjusted as needed for actual application, such as at the time before the periodic maintenance schedule and the following occurrence of actual device failure, so that unnecessary maintenance action can be reduced and the maintenance cost as consequence.

FIG. 7 shows the sectional views of the substrate comprising the adjacent actual device 2 and some dummy devices 4. Dummy devices 4 have increasing lifetime to provide early warning of actual device failure with different warning intensity. Dummy devices 4 with smaller ratio of L2/L1 in the solder joint layer 42 will have higher warning intensity when the dummy device 4 fails.

FIG. 8 shows a block diagram illustrating an exemplary electrical circuit of the present invention. Condition of the actual device 2, said the damage in the solder joint layer 22, in signal processing circuit is electrically detected and compared with that of the dummy device 4 in the life time prediction circuit by the detector in control circuit. Once the dummy device 4 fails, alarm will be activated indicating the imminent failure of the actual device 2.

FIG. 9 shows the voltage change and the number of cycles for the actual device 2 and dummy devices 4 with the decreasing percentage area of the inner solder joint part 42b. Dummy devices 4 are placed closely to the actual device 2. The lifetime or the cycle to failure of the dummy device 4 becomes longer as decreasing the ratio of L2/L1 in the solder joint 42.

FIG. 10 shows the lifetime prediction of the actual device 2 according to the lifetime of dummy devices 4. The lifetime of the actual device 2 is predicted according to the relationship of L2/L2 ratio in the solder joint layer 42 of the dummy devices 4 and the resulted lifetime, shown in FIG. 9, with the predetermined failure criterion of voltage change corresponding to the certain delamination percentage of solder joint layer.

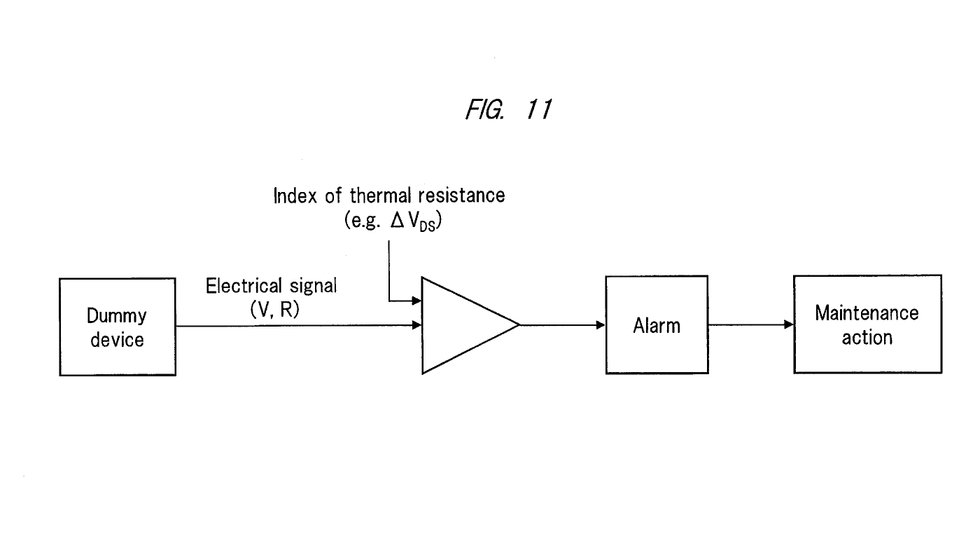

FIG. 11 shows a block diagram illustrating an exemplary system for providing early warning of actual device failure. The electrical signal of the dummy device 4 is monitored and compared with the failure criterion or index of thermal resistance. Once the electrical signal of the dummy device 4 reaches the index of thermal resistance such as the predetermined “delta V_{DS,}” alarm will be activated and informs the need to perform maintenance action.

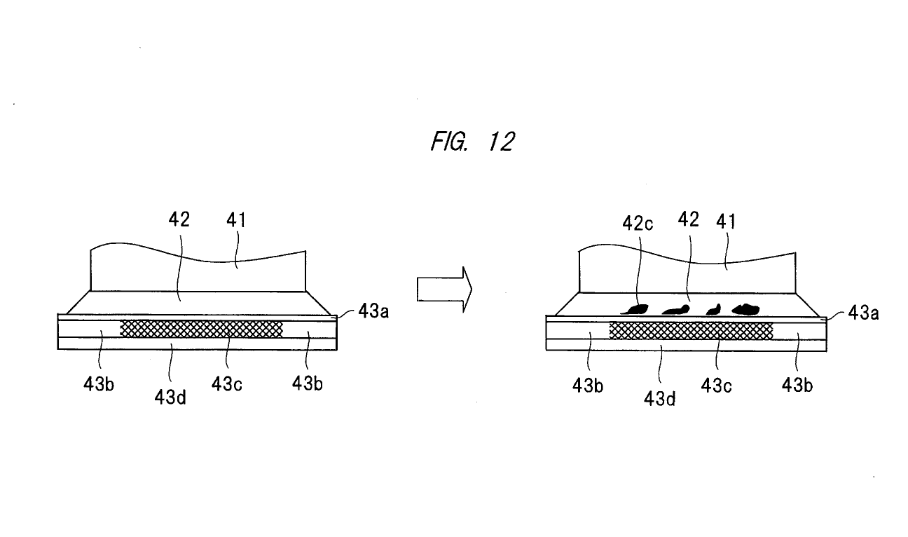

FIG. 12 shows the first example of the dummy device 4 and the manufacturing method. The dummy device 4 has a fragile inner solder joint part 42b due to brittle precipitation 42c formed in the inner solder joint part 42b. This brittle precipitation 42c is produced by using the electroless barrier layer 41b, such as electroless Ni layer which contains phosphorus impurity, for the inner solder joint part 42b. This phosphorus impurity diffuses to the inner solder joint part 42b and creates brittle precipitation and or brittle intermetallic compound.

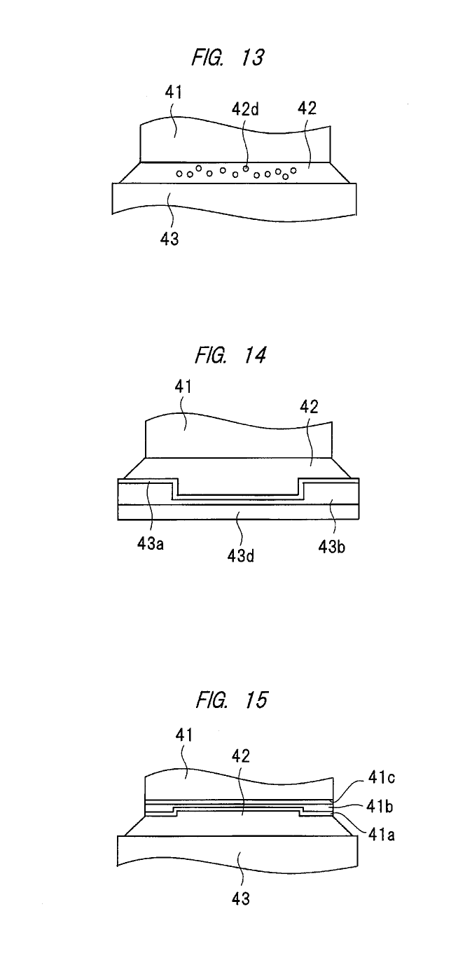

FIG. 13 shows the second example of the dummy device 4. The dummy device 4 has a fragile inner solder joint part 42b due to voids 42d formed in the inner solder joint part 42b. FIG. 14 shows the second example of manufacturing method of the dummy device 4. These voids 42d can be the extensively formed Kirkendall voids in the inner solder joint part 42b when exposed to the high temperature above 150° C. This may be provided by using substrate metallization 43 comprising the thinner barrier layer thickness on substrate corresponding to the inner solder joint part 42b than that corresponding to the outer solder joint part 42a.

FIG. 15 shows the third example of manufacturing method of the dummy device 4. These voids 42d can be the extensively formed Kirkendall voids in the inner solder joint part 42b when exposed to the high temperature above 150° C. This may be provided by using chip metallization comprising the thinner barrier layer thickness 41b on chip corresponding to the inner solder joint part 42b than that corresponding to the outer solder joint part 42a.

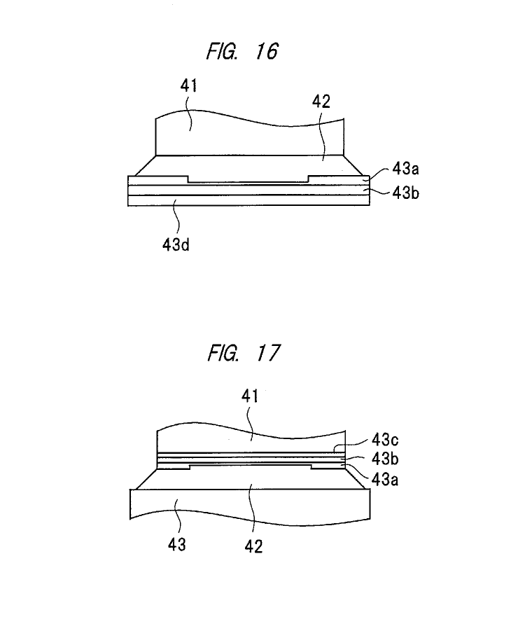

FIG. 16 shows the fourth example of the manufacturing method of the dummy device 4. Voids 42d in the inner solder joint part 42b may be formed due to the poor solder wettability on the inner surface part of substrate metallization 43 and or the dummy semiconductor chip 41 relative to the outer solder joint part due to the thinner thickness of gold finish 43a on the inner solder joint part of substrate metallization 43.

FIG. 17 shows the fifth example of the manufacturing method of the dummy device 4. Voids 42d in the inner solder joint part 42b may be formed due to the poor solder wettability on the inner surface part of the dummy semiconductor chip 41 relative to the outer solder joint part due to the thinner thickness of gold coating 41a on the inner metallization part of the dummy semiconductor chip 43.

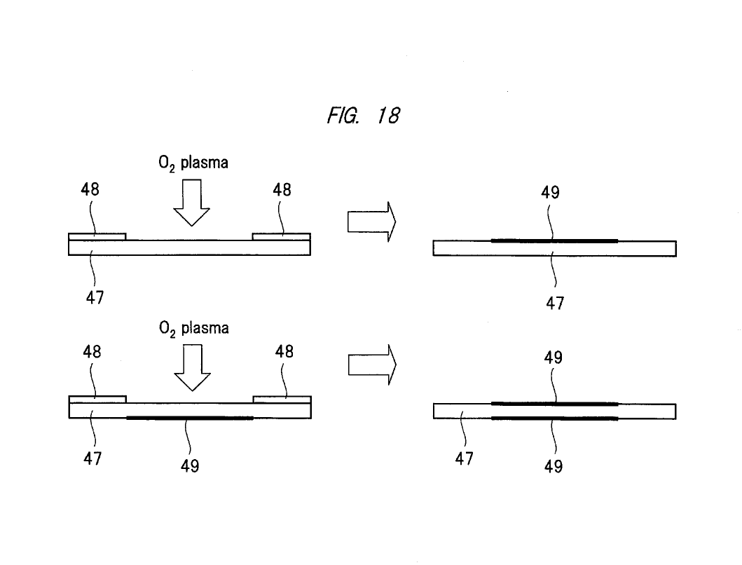

FIG. 18 shows the sixth example of the manufacturing method of the dummy device 4. Voids 42d in the inner solder joint part 42b may be formed due to the poor solder wettability on the inner surface part of substrate metallization 43 and or the dummy semiconductor chip 41 relative to the outer solder joint part of substrate metallization 43 and or the dummy semiconductor chip 41. This poor wettability is produced by oxidizing only the inner part of a solder film 47 corresponding to the inner solder joint part 42b through O₂ plasma. Oxidation on the outer part of the solder film 47 corresponding to the outer solder joint part 42a is prevented by using mask during the treatment of O₂ plasma. Oxidation on the inner solder joint part of the solder film 47 can be performed on one side or both sides. The resulted oxide layer 49 on the inner part of the solder film 47 corresponding to the inner solder joint part 42b before reflow process creates voids 42d in the inner solder joint part 42b of the solder joints 42 due to the poor solder wettability during the reflow process.

FIG. 19 shows the seventh example of the manufacturing method of the dummy device 4. Voids 42d may be also formed by the trapped air in the inner joint part 42b during reflow process by using a solder film 47 with the discontinuous structure such as some holes 47a in the middle part of the solder film 47.

FIG. 20 shows the eight example of the manufacturing method of the dummy device 4. Voids 42d may be also formed by the trapped air in the inner joint part 42b during reflow process by using a solder film 47 with the discontinuous structure such as a big hole 47a in the middle filled with some solder balls 47b.

The present invention is not limited to the above embodiments, but can be modified variously without departing from the scope of the present invention.

### REFERENCE SIGNS LIST

1 . . . Electronic device
2 . . . Actual device with normal joint
3 . . . Actual device with fragile joint
4 . . . Dummy or canary device
5 . . . Substrate
21 . . . Semiconductor chip
22 . . . Solder joint of actual device
23 . . . Substrate metallization of actual device
24 . . . Substrate metallization of actual device
25 . . . Wire bond
26 . . . Semiconductor chip electrode pad
31 . . . Semiconductor chip
33 . . . Substrate metallization of actual device
34 . . . Substrate metallization of actual device
35 . . . Wire bond
36 . . . Semiconductor chip electrode pad
41 . . . Dummy semiconductor chip
41a . . . Gold coating on dummy semiconductor chip
41b . . . Ni barrier layer on dummy semiconductor chip
41c . . . Electrode on dummy semiconductor chip
42 . . . Solder joint of dummy device
42a . . . Outer solder joint part of dummy device
42b . . . Inner solder joint part of dummy device
42c . . . Precipitation in the inner solder joint part of dummy device
42d . . . Voids in the inner solder joint part of dummy device
43 . . . Substrate metallization of dummy device
43a . . . Gold coating on substrate metallization of dummy device
43b . . . Electrolytic Ni barrier layer on substrate metallization of dummy device
43c . . . Electroless Ni barrier layer on substrate metallization of dummy device
43d . . . Cu layer on substrate metallization of dummy device
44 . . . Substrate metallization of dummy device
45 . . . Wire bond of dummy device
46 . . . Dummy semiconductor chip electrode pad
47 . . . Solder film
48 . . . Mask
49 . . . Oxide layer on the inner part of solder film

1. A substrate for providing early warning of degradation in a semiconductor device comprising: an actual device comprising a semiconductor component and a solder joint; and a dummy device closely placed to the actual device on the substrate and connected electrically in parallel circuit to the actual device, comprising a dummy semiconductor component and a solder joint comprising an outer solder joint part and an inner solder joint part, wherein the outer solder joint part has same characteristic to the solder joint of the actual device and the inner solder joint part accelerates the crack growth faster than the outer solder joint, and percentage area of outer solder joint part is smaller than the predetermined failure criterion of delamination percentage in actual device corresponding to the threshold value of electrical change.

2. The substrate according to claim 1, further comprising one or more dummy device(s) closely placed to around of the actual device, connected electrically in parallel circuit to the other dummy device(s) and the actual device.

3. A dummy device according to claim 1, wherein the inner solder joint part comprises the formation selected from a group consisting of brittle precipitation, brittle intermetallic compound, the formation of voids and weak strength solder joint at the interface.

4. The dummy device according to claim 3, wherein the brittle precipitation and/or brittle intermetallic compound in the inner solder joint part is formed by using a barrier layer on the substrate, wherein the barrier layer for inner solder joint part is made of an electroless Ni and the barrier layer for outer solder joint part is made of an electrolytic Ni.

5. The dummy device according to claim 3, wherein the formation of voids is the extensive formation of Kirkendall voids.

6. Method for manufacturing the dummy device according to claim 5,
providing the extensive formation of Kirkendall voids into the inner solder joint part by using a substrate surface of which the thickness of the barrier layer for the inner solder joint part of the substrate surface is thinner than the thickness of the barrier layer for the outer solder joint part;
obtaining the thickness of the barrier layer for the inner solder joint part which is equal to or less than 80% of the thickness of the barrier layer for the outer solder joint part; and,
exposing the inner solder joint part to the temperature above 150° C. after reflow soldering process and/or during the actual application environment above 150° C., wherein this method is applicable to high temperature condition (above 150° C.).

7. Method for manufacturing the dummy device according to claim 6, wherein the substrate is a dummy semiconductor chip surface.

8. Method for manufacturing the dummy device according to claim 5, wherein the formation of voids and or weak strength solder joint at the interface is performed by the poor solder wettability on the substrate surface or dummy semiconductor chip surface for the inner solder joint part during reflow process.

9. Method for manufacturing the dummy device according to claim 8, wherein gold coating thickness of substrate surface for the inner solder joint part is equal to or less than 30% of thickness of the substrate surface for the outer solder joint part.

10. Method for manufacturing the dummy device according to claim 8, wherein gold coating thickness of semiconductor chip surface for the inner solder joint part is equal to or less than 30% of gold coating thickness of the semiconductor chip surface for the outer solder joint part.

11. Method for manufacturing the dummy device according to claim 8, wherein an oxide layer with the thickness equal to or more than 1 nm is formed on the one side and/or both sides of the solder film surface corresponding to the inner solder joint part by O₂ plasma, and wherein the solder film surface corresponding to the outer solder joint part is covered with a mask to prevent the oxide layer from being formed on the outer solder joint part of solder film.

12. Method for manufacturing the dummy device according to claim 3, wherein the voids in the inner solder joint part are trapped air during the reflow process by using the discontinuous structure in the middle part of the solder film.

13. Method for manufacturing the dummy device according to claim 12, wherein solder film is patterned with some holes in the middle part or solder film.

14. Method for manufacturing the dummy device according to claim 12, wherein solder film is patterned with an open area or a big hole filled with some solder balls in the middle part of solder film.

15. An inner solder joint part according to claim 1 comprising the formation selected from a group consisting of brittle precipitation, brittle intermetallic compound and the formation of voids.

16. The inner solder joint part according to claim 15, wherein the brittle precipitation and brittle intermetallic compound is formed by a barrier layer on the substrate, wherein the barrier layer for inner solder joint part is made of an electroless Ni and the barrier layer for outer solder joint part is made of an electrolytic Ni.

17. The inner solder joint part according to claim 15, wherein the formation of voids is the extensive formation of Kirkendall voids.

18. The inner solder joint part according to claim 15, wherein the extensive formation of Kirkendall voids is provided by using the substrate surface and/or the semiconductor chip surface comprising the thickness of the barrier layer for the inner solder joint part is equal to or less than 80% the thickness of the barrier layer for the outer solder joint part.

19. The inner solder joint part according to claim 15, wherein the formation of voids and/or weak strength solder joint at the interface are formed by the poor solder wettability on the substrate surface and/or the semiconductor chip surface during the reflow process.

20. The inner solder joint part according to claim 19, wherein the gold coating thickness of surface for the inner solder joint part is equal to or less than 30% of the gold coating thickness of the surface for the outer solder joint part.

21. The inner solder joint part according to claim 19, wherein the solder film with an oxide layer with the thickness equal to or more than 1 nm is formed on the one side and/or both sides of the solder film surface corresponding to the inner solder joint part by O₂ plasma, wherein the solder film surface corresponding to the outer solder joint part is covered with a mask to prevent the oxide layer from being formed on the solder film surface corresponding to the outer solder joint part.

22. The inner solder joint part according to claim 15 comprising voids, wherein the voids are formed as trapped air during the reflow process by using the solder film with the discontinuous structure in the middle part of solder film.

23. The inner solder joint part according to claim 22, wherein the discontinuous structured solder film is patterned with some holes in the middle part or solder film.

24. The inner solder joint part according to claim 22, wherein the discontinuous structured solder film is patterned with an open area or a big hole filled with some solder balls in the middle part of solder film.
